(19) United States
(12) Patent Application Publication
(10) Pub. No.: US 2007/0274051 A1
(43) Pub. Date: Nov. 29, 2007

(54) Heat-dissipating backlighting module for use in a flat panel display

(75) Inventors: Alex Horng, Kaohsiung (TW); Masaharu Miyahara, Taipei (TW); Te-Chen Liu, Taipei (TW)

Correspondence Address: BIRCH STEWART KOLASCH & BIRCH, PO BOX 747, FALLS CHURCH, VA, 22040-0747, US

(73) Assignee: Sunonwealth Electric Machine Industry Co., Ltd.

(21) Appl. No.: 11/491,882

(22) Filed: Jul. 25, 2006

(30) Foreign Application Priority Data
May 23, 2006 (TW) 095118265

(51) Int. Cl. H05K 7/20

(52) U.S. Cl. 361/710

(57) ABSTRACT

A heat-dissipating backlighting module includes a heat-dissipating plate to combine with a back light unit. The heat-dissipating plate has an assembling space provided on a first side, and a vertically extended air-cooling structure provided on a second side. The vertically extended air-cooling structure includes a plurality of vertically extended fins and a plurality of vertically extended air-circulating channels. In assembling, the assembling space of the heat-dissipating plate receives the heat back light unit having a light source that projects light on a flat panel display. The vertically extended fins and vertically extended air-circulating channels can guide airflows running upwardly in a vertical direction so as to dissipate heats from the vertically extended fins and the vertically extended air-circulating channels.

### BACKGROUND OF THE INVENTION

1. Field of the Invention

The present invention relates to a heat-dissipating backlighting module for use in a flat panel display. More particularly, the present invention relates to the heat-dissipating backlighting module having a heat-dissipating plate that has a first side to arrange a heat back light unit, and a second side to provide a vertically extended air-cooling structure for dissipating waste heats generated from the heat back light unit and the flat panel display.

2. Description of the Related Art

Referring initially to FIG. 1, a conventional heat-dissipating backlighting module for use in the flat panel display typically includes a backlighting plate 91, a heat-dissipating plate 92, a pair of heat sink sets 93 and a pair of heat-dissipating fans 94. The backlighting plate 91 provides a plurality of light emitting diodes (“LEDs”) arranged thereon, which are not shown in FIG. 1. The backlighting plate 91 is attached to a rear portion of a flat panel display (“FPD”) 90 so as to provide a light source that emits lights penetrating the flat panel display 90.

Typically, the heat-dissipating plate 92 is made from a metal such as aluminum or copper having a good thermal conductivity. In addition, the heat-dissipating plate 92 further provides a set of liquid circulating pipes 920 embedded therein. A coolant or other equivalent liquid may run along the liquid circulating pipes 920 for circulation while operating the heat-dissipating backlighting module.

In assembling operation, one side of the heat-dissipating plate 92 is attached to a corresponding side of the backlighting plate 91 such that the metal and coolant can conduct waste heats generated from the LEDs of the backlighting plate 91. Mounted on opposite distal ends of the heat-dissipating plate 92 are the heat sink sets 93 each of which provides a plurality of air channels 930 extending in a longitudinal direction of the heat-dissipating plate 92. Further mounted on each of the heat sink sets 93 is the heat-dissipating fan 94 which has a fan wheel 940 to drive a cooling airflow. In this manner, the cooling air may be forced to pass through the air channels 930 of the corresponding heat sink set 93.

When illuminating the LEDs of the backlighting plate 91, heats generated from the LEDs may be conducted to the heat-dissipating plate 92 and the coolant contained in the liquid circulating pipes 920. Circulations of the heated coolant may create a convection of the heats for implementing liquid heat-dissipating operation. Once the heated coolant has passed through a section of the liquid circulating pipes 920 located around the heat sink sets 93, the heat may be conducted to the heat sink sets 93 and dissipated from the heat sink sets 93 into the ambient environment by the heat-dissipating fan 94. In this manner, the heated coolant may be cooled and relatively contracted if the heats are dissipated properly. Accordingly, the low-temperature coolant may be automatically returned along the liquid circulating pipes 920 due to its circulation.

In general, a number of design limitations and drawbacks exist for the above flat panel display 90. By way of example, the flat panel display 90 is currently designed to have a thin thickness for a compact design, but the arrangement of the heat sink sets 93 and heat-dissipating fan 94 may inevitably increase a significant thickness. Another problem with such a design of the flat panel display 90 is due to the fact that the arrangement of the air channels 930 are extended in the longitudinal direction of the heat sink sets 93 which is generally disposed in a horizontal direction of the flat panel display 90. Disadvantageously, the heated airflow running in the air channels 930 driven by the heat-dissipating fans 94 cannot be directly discharged in a desired vertical direction of the flat panel display 90 and cannot conform the fact that hot air is automatically rising in the ambient environment. In the large-size flat panel display 90, the heat sink sets 93 and heat-dissipating fans 94 are provided on positions of the opposite distal ends of the heat-dissipating plate 92, but the only liquid circulating pipes 920 of the heat-dissipating plate 92 are provided on a center area of the backlighting plate 91 that may lower the heat-dissipating efficiency. Therefore, it would be undesirable that such an arrangement of the heat sink sets 93 and heat-dissipating fans 94 results in an unbalanced distribution of the heat-dissipating efficiency on various areas of the backlighting plate 91. If the heat is not properly dissipated from the center area of the backlighting plate 91, there is a greater chance of damaging the flat panel display 90 and backlighting plate 91. Hence, there is a need for improving the conventional heat-dissipating backlighting module for the back light unit.

As is described in greater detail below, the present invention intends to provide a heat-dissipating backlighting module for use in the flat panel display. The heat-dissipating backlighting module includes a heat-dissipating plate that has a vertically extended air-cooling structure provided on a second side for dissipating heats generated from a back light unit and the flat panel display, and an assembling space provided on a first side to receive the back light unit. The vertically extended air-cooling structure includes a plurality of vertically extended fins and a plurality of vertically extended air-circulating channels. The heat generated from the heat back light unit can be directly conducted to the vertically extended fins and vertically extended air-circulating channels in such a way as to mitigate and overcome the above problem.

### SUMMARY OF THE INVENTION

The primary objective of this invention is to provide a heat-dissipating backlighting module for use in the flat panel display, wherein an assembling space is provided on a side of a heat-dissipating plate to receive the back light unit. Accordingly, the total thickness of the heat-dissipating backlighting module is reduced.

The secondary objective of this invention is to provide the heat-dissipating backlighting module for use in the flat panel display, wherein an assembling space is provided on a first side of a heat-dissipating plate to receive the back light unit, and a vertically extended air-cooling structure is provided on a second side of the heat-dissipating plate. Accordingly, the vertically extended air-cooling structure can enhance the efficiency of heat dissipation.

The heat-dissipating backlighting module in accordance with an aspect of the present invention includes a heat-dissipating plate to combine with a back light unit. The heat-dissipating plate has an assembling space provided on a first side, and a vertically extended air-cooling structure provided on a second side. The vertically extended air-cooling structure includes a plurality of vertically extended fins and a plurality of vertically extended air-circulating channels. In assembling, the assembling space of the heat-dissipating plate receives the heat back light unit having a light source that projects light on the flat panel display. The vertically extended fins and vertically extended air-circulating channels can guide airflows running upwardly in a vertical direction so as to dissipate heats from the vertically extended fins and vertically extended air-circulating channels.

In a separate aspect of the present invention, the assembling space is integrally formed on the first side of the heat-dissipating plate.

In a further separate aspect of the present invention, the assembling space is formed from an assembling rack attached to the first side of the heat-dissipating plate.

In a yet further separate aspect of the present invention, the assembling space is extended in a longitudinal or lateral direction of the heat-dissipating plate.

Further scope of the applicability of the present invention will become apparent from the detailed description given hereinafter. However, it should be understood that the detailed description and specific examples, while indicating preferred embodiments of the invention, are given by way of illustration only, since various will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is an assembled perspective view illustrating the combination of a heat-dissipating backlighting module a flat panel display in accordance with the prior art;

FIG. 2 is an exploded perspective view illustrating a heat-dissipating backlighting module and a flat panel display in accordance with a first embodiment of the present invention;

FIG. 3 is an assembled, cross-sectional view illustrating the assembled relation of the heat-dissipating backlighting module and the flat panel display in accordance with the first embodiment of the present invention;

FIG. 4 is an assembled, cross-sectional view, similar to FIG. 3, illustrating the assembled relation of the heat-dissipating backlighting module and the flat panel display in accordance with the second embodiment of the present invention;

FIG. 5 is an exploded perspective view illustrating the heat-dissipating backlighting module and the flat panel display in accordance with the third embodiment of the present invention; and

FIG. 6 is an assembled, cross-sectional view, similar to FIG. 3, illustrating the assembled relation of the heat-dissipating backlighting module and the flat panel display in accordance with the third embodiment of the present invention;

### DETAILED DESCRIPTION OF THE INVENTION

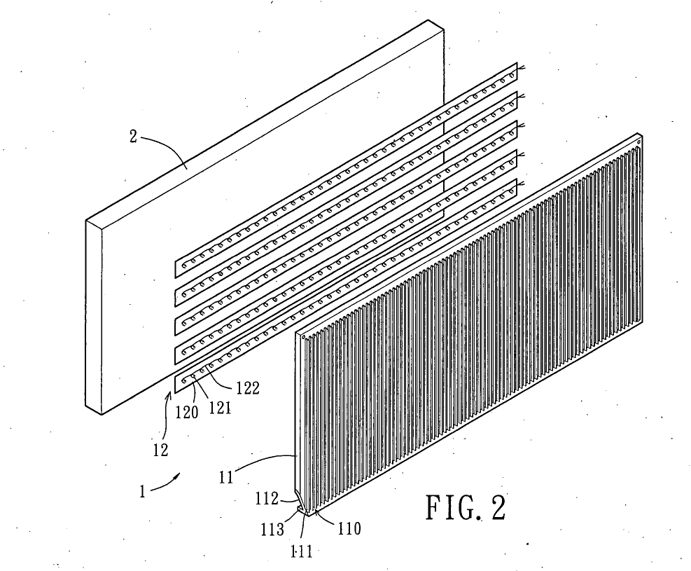

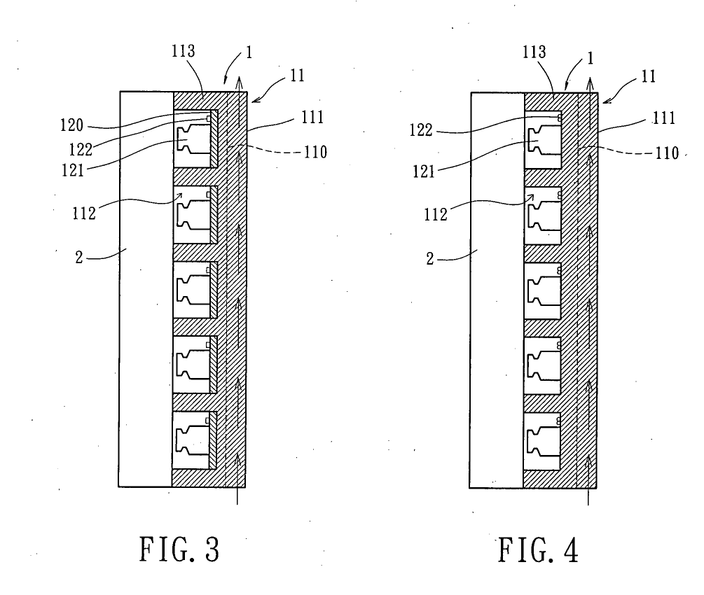

Referring now to FIGS. 2 and 3, views of a heat-dissipating backlighting module in accordance with the first embodiment of the present invention are illustrated. The heat-dissipating backlighting module designated numeral 1 generally includes a heat-dissipating plate designated numeral 11 and a back light unit designated numeral 12. The heat-dissipating plate 11 and the back light unit 12 are assembled to form the heat-dissipating backlighting module 1 that is combined with a rear surface of a flat panel display designated numeral 2. In operation, the heat-dissipating backlighting module 1 functions as a light source that projects light on the flat panel display 2. In a preferred embodiment, the heat-dissipating backlighting module 1 is applied to the flat panel display 2 which is generally selected from a liquid crystal display (“LCD”) or a plasma display panel (“PDP”).

Still referring to FIGS. 2 and 3, construction of the heat-dissipating plate 11 shall be described in detail. In this preferred embodiment, the heat-dissipating plate 11 is made from a metal such as aluminum, copper, gold, silver or alloy thereof having a good thermal conductivity. The heat-dissipating plate 11 includes a plurality of vertically extended air-circulating channels 110, a plurality of vertically extended fins 111, at least one assembling compartment 112 and at least one supporting wall 113. The heat-dissipating plate 11 has a first side and a second side opposite to the first side. In a preferred embodiment, the vertically extended air-circulating channels (i.e. grooves) 110 are integrally recessed and extended in parallel on the first side of the heat-dissipating plate 11. Also, the vertically extended fins 111 are integrally protruded and extended in parallel on the first side of the heat-dissipating plate 11. The two adjacent fins 111 define each of the vertically extended air-circulating channels 110. In this manner, the combination of the vertically extended air-circulating channels 110 and vertically extended fins 111 constitute a vertically extended air-cooling structure. When heating the heat-dissipating plate 11, airflows may dissipate away heats from the vertically extended air-circulating channels 110 and vertically extended fins 111 to the ambient environment.

On the other hand, formed on the second side of the heat-dissipating plate 11 are the assembling compartment 112 and supporting wall 113. To provide an assembling space for receiving the back light unit 12, there provides the assembling compartment 112. Preferably, the assembling compartment 112 is extended in a longitudinal or lateral direction of the heat-dissipating plate 11. In a preferred embodiment, the assembling compartment 112 is integrally formed on the second side of the heat-dissipating plate 11, and the supporting walls 113 confine each of the assembling compartments 112. The supporting wall 113 is of an annular wall having a predetermined height that sufficiently receives the entire thickness of the back light unit 12 such that no portion of the back light unit 12 extends beyond the height of the supporting wall 113 when the heat-dissipating plate 11 and back light unit 12 are assembled to form the heat-dissipating backlighting module 1. Accordingly, the back light unit 12 is completely received in the assembling compartment 112. However, the back light unit 12 preferably has a height to provide a consistent height with a top surface of the supporting wall 13. In assembling operation, the supporting wall 113 of the heat-dissipating plate 11 is engaged with the rear surface of the flat panel display 2 so as to intensify the assembled relationship of the heat-dissipating backlighting module 1 and the flat panel display 2.

The construction of the back light unit 12 shall be described in detail, by still referring to FIGS. 2 and 3. Once assembled, the back light unit 12 is received in the assembling compartment 112 of the heat-dissipating plate 11. In the first embodiment, the back light unit 12 includes a substrate 120, at least one illumination device 121 and at least one conductive member 122. The substrate 120 may be constructed from a printed circuit board (“PCB”) or a flexible printed circuit board. Preferably, the substrate 120 is mounted on a bottom surface of the assembling compartment 112 by means of adhesion or screw connection. The illumination device 121 is arranged on the substrate 120 and constructed from a series of LEDs, white LED for example, which are preferably equi-spaced on the substrate 120. The conductive member 122 is preferably selected from a printed circuit if the substrate 120 is constructed from the printed circuit board or flexible printed circuit board. The conductive member 122 electrically connects the illumination device 121 with an exterior control circuit (not shown). In an alternative embodiment, the conductive member 122 is selected from an enameled wire according to the design needs.

Still referring to FIG. 3, when assembling the heat-dissipating backlighting module 1 and the flat panel display 2, the supporting wall 113 of the heat-dissipating plate 11 is engaged with the rear surface of the flat panel display 2. The back light unit 12 emits white light to penetrate through the flat panel display 2 such that images may appear on a front surface of the flat panel display 2. Meanwhile, heats generated from the illumination device 121 of the back light unit 12 are directly transmitted from the assembling compartment 112 to the vertically extended air-cooling structure of the heat-dissipating plate 11 due to the fact that the heat-dissipating plate 11 has a good thermal conductivity. Subsequently, the vertically extended air-circulating channels 110 and vertically extended fins 111 can dissipate the heats to the ambient environment by means of the action of air convection. In heat-dissipating operation, cooling airflows may automatically pass the vertically extended air-circulating channels 110 and vertically extended fins 111 in a vertical direction (indicated by the direction arrows in FIG. 3) to accomplish heat exchange in an efficient manner. Advantageously, the vertically extended air-cooling structure may enhance the efficiency of heat dissipation by allowing the airflow to run upwardly. The heat-dissipation operation will be further described in greater detail below.

With continued reference to FIG. 3, cool air may enter the heat-dissipating backlighting module 1 from a bottom portion of the vertically extended air-circulating channels 110 of the heat-dissipating plate 11 which is placed in an upright position. Once entered, the cool air automatically runs upwardly and passes the vertically extended air-circulating channels 110 and vertically extended fins 111 for accomplishing heat exchange. The heated air exchanged from the vertically extended air-cooling structure may be discharged from a top portion of the vertically extended air-circulating channels 110 in the event for dissipating heats to the ambient environment. A continuous heat exchange in the heat-dissipating backlighting module 1 is helpful in transmitting heats from the substrate 120 and illumination device 121 of the back light unit 12 to the heat-dissipating plate 11. In this way, the combination of heat conduction in the heat-dissipating plate 11 with heat exchange on the vertically extended air-cooling structure carries out a higher efficiency of heat dissipation in the heat-dissipating backlighting module 1. In a preferred embodiment, a fan unit (not shown) is provided in a casing (not shown) of the flat panel display 2 for ventilation purpose if desired. The fan unit may be disposed at the bottom portion of the vertically extended air-circulating channels 110 when the heat-dissipating plate 11 is positioned in the upright position. Preferably, the fan unit is helpful in enhancing the efficiency of heat exchange by forcing the air entering the heat-dissipating backlighting module 1 and discharging therefrom. It is apparent from FIG. 2 that no additional fan unit is applied in practicing the heat-dissipating backlighting module 1 in accordance with the first embodiment of the present invention. In addition, the entire back light unit 12 is completely embedded in the assembling compartment 112 that can reduce the entire thickness of the heat-dissipating backlighting module 1.

Turning now to FIG. 4, an assembled, cross-sectional view, similar to FIG. 3, of the assembled relation of the heat-dissipating backlighting module and the flat panel display in accordance with the second embodiment of the present invention is illustrated. In comparison with the first embodiment, the back light unit 12 of the second embodiment provides the illumination device 121 and conductive member 122 directly mounted on the bottom surface of the assembling compartment 112 for accomplishing a simplified structure that omits the arrangement of the substrate 120 in the first embodiment. Preferably, the conductive member 122 is selected from an enamel-insulated wire having insulating layer coated thereon. In the preferred embodiment, the back light unit 12 is mounted on the bottom surface of the assembling compartment 112 by adhesion, engagement or snap fitting. Advantageously, the design of the back light unit 12 of the second embodiment can omit a specific thickness occupied by the substrate 120 for reducing the total thickness; or the design of the back light unit 12 is suitable for accommodating a large size of the illumination device 121.

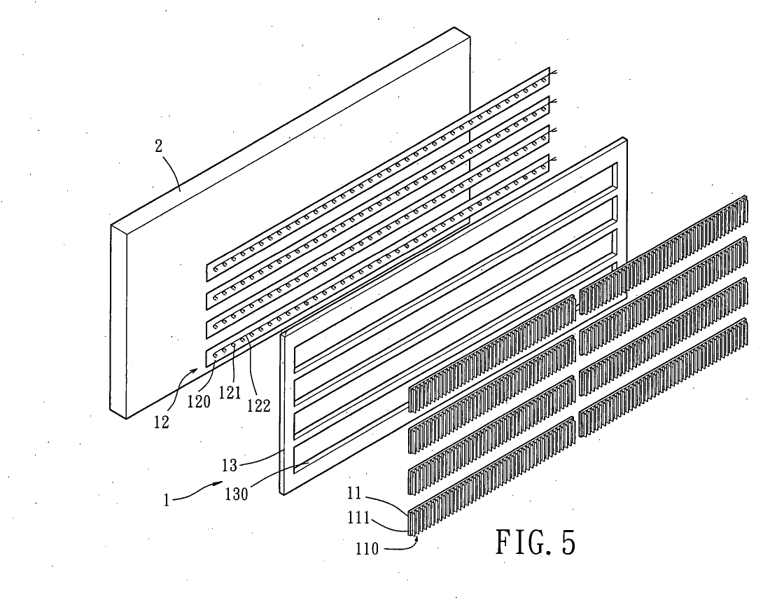

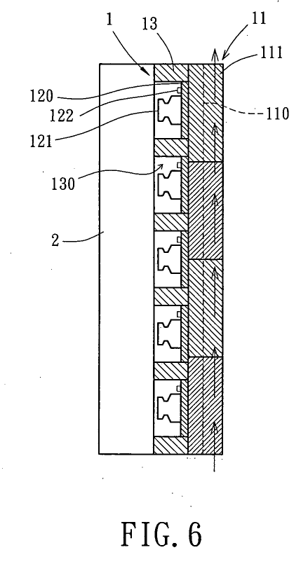

Turning now to FIGS. 5 and 6, views of the heat-dissipating backlighting module in accordance with the third embodiment of the present invention are illustrated. In comparison with the first and second embodiments, the heat-dissipating backlighting module 1 of the third embodiment further includes an assembling rack 13 mounted on the heat-dissipating plate 11. The assembling rack 13 provides at least one assembling space 130 for receiving the illumination device 121. In assembling, one side of the assembling rack 13 is mounted to the rear surface of the flat panel display 2 while the other side is combined with a set of the heat-dissipating plates 11. Consequently, the assembling rack 13 is sandwiched in-between the heat-dissipating plates 11 and the flat panel display 2.

In the third embodiment, the assembling rack 13 is made from a metal or alloy (e.g. aluminum, copper, gold, silver or alloy thereof) having a good thermal conductivity. In this way, the heat-dissipating plates 11 and assembling rack 13 are separately made from similar or dissimilar materials. In an alternative embodiment, the assembling rack 13 is made from a non-metal material such as plastic or foam material. Formed in the combination of the heat-dissipating plates 11 and assembling rack 13 is a set of assembling compartments for correspondingly accommodating a set of the back light units 12. Preferably, the back light units 12 may not extended beyond a thickness of the assembling rack 13. When the heat-dissipating plates 11 are connected each other in a common plane, the vertically extended air-circulating channels 110 and vertically extended fins 111 of the heat-dissipating plate 11 is aligned with those of the adjacent heat-dissipating plate 11. Each of the back light units 12 has a substrate 120 directly mounted on the corresponding heat-dissipating plate 11. Advantageously, the combination of the heat-dissipating plates 11 and assembling rack 13 of the third embodiment can accomplish an increase of the efficiency of heat dissipation, and reduce the total thickness of the heat-dissipating backlighting module 1.

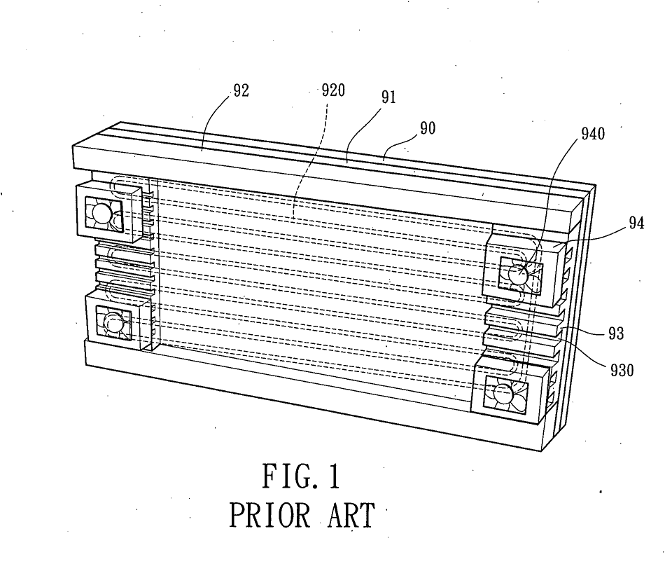

As has been discussed above, the conventional heat-dissipating backlighting module results in an unbalanced distribution of the efficiency of heat dissipation due to the arrangement of the heat sink sets 93 and heat-dissipating fans 94, as shown in FIG. 1. Conversely, the first side of the heat-dissipating plate 11 of the present invention is formed with the vertically extended air-circulating channels 110 and vertically extended fins 111 while the second side is formed with the assembling compartment 112, as best shown in FIG. 2. In the heat-dissipating backlighting module 1, airflows can automatically run upwardly and pass through the vertically extended air-circulating channels 110 and vertically extended fins 111. Advantageously, the combination of the heat-dissipating plate 11 and back light unit 12 can simplify the structure, enhance the efficiency of heat dissipation and reduce the total thickness of the heat-dissipating backlighting module 1.

Although the invention has been described in detail with reference to its presently preferred embodiment, it will be understood by one of ordinary skill in the art that various modifications can be made without departing from the spirit and the scope of the invention, as set forth in the appended claims.

What is claimed is:

1. A heat-dissipating backlighting module for use in a flat panel display, comprising:
at least one heat-dissipating plate having a first side and a second side, the heat-dissipating plate including a plurality of vertically extended air-circulating channels and a plurality of vertically extended fins provided on the first side, the heat-dissipating plate further including at least one assembling space arranged on the second side; and
at least one back light unit received in the assembling space of the heat-dissipating plate, the back light unit including at least one light source that projects light on the flat panel display.

2. The heat-dissipating backlighting module for use in the flat panel display as defined in claim 1, wherein the vertically extended air-circulating channels and the vertically extended fins are extended in a vertical direction to allow airflows running upwardly along the vertically extended air-circulating channels.

3. The heat-dissipating backlighting module for use in the flat panel display as defined in claim 1, wherein the assembled space is extended in a longitudinal direction of the heat-dissipating plate and integrally formed on the second side of the heat-dissipating plate, a supporting wall confines the assembling space and engages with the flat panel display.

4. The heat-dissipating backlighting module for use in the flat panel display as defined in claim 1, wherein the assembled space is extended in a lateral direction of the heat-dissipating plate and integrally formed on the second side of the heat-dissipating plate, a supporting wall confines the assembling space and engages with the flat panel display.

5. The heat-dissipating backlighting module for use in the flat panel display as defined in claim 1, wherein further including at least one supporting rack mounted on the heat-dissipating plate, one side of the assembling rack is mounted to the rear surface of the flat panel display while the other side is combined with the heat-dissipating plate.

6. The heat-dissipating backlighting module for use in the flat panel display as defined in claim 1, wherein the back light unit is completely received in the assembling space of the heat-dissipating plate.

7. The heat-dissipating backlighting module for use in the flat panel display as defined in claim 1, wherein the light source of the back light unit is mounted on a bottom surface of the assembling space.

8. The heat-dissipating backlighting module for use in the flat panel display as defined in claim 1, wherein the back light unit includes at least one conductive member electrically connecting the light source with an exterior control circuit.

9. The heat-dissipating backlighting module for use in the flat panel display as defined in claim 8, wherein the conductive member is selected from a printed circuit or an enameled wire.

10. The heat-dissipating backlighting module for use in the flat panel display as defined in claim 1, the back light unit includes a substrate on which the light source is arranged, the substrate is mounted on a bottom surface of the assembling space.

11. The heat-dissipating backlighting module for use in the flat panel display as defined in claim 10, wherein the substrate is selected from a printed circuit board or a flexible printed circuit board.

12. The heat-dissipating backlighting module for use in the flat panel display as defined in claim 1, wherein the light source is selected from a LED.

13. The heat-dissipating backlighting module for use in the flat panel display as defined in claim 1, wherein the flat panel display includes a casing in which to provide a fan unit, the fan unit is located at a bottom portion of the heat-dissipating plate.
